(19) United States
(12) Patent Application Publication
(10) Pub. No.: US 2026/0047434 A1
(43) Pub. Date: Feb. 12, 2026

(54) METHOD FOR PRODUCING A SEMICONDUCTOR MODULE HAVING AT LEAST ONE SEMICONDUCTOR ARRANGEMENT AND A HEATSINK

(71) Applicant: Siemens Aktiengesellschaft, 80333 München (DE)

(72) Inventors: MATTHIAS NÄHRIG, Hemhofen (DE); ROMAN KÖGLER, Nürnberg (DE); DANIEL KAPPAUF, Gräfenberg (DE); JENS SCHMENGER, Forchheim (DE); STEFAN PFEFFERLEIN, Heroldsberg (DE)

(73) Assignee: Siemens Aktiengesellschaft, 80333 München (DE)

(21) Appl. No.: 19/100,471

(22) PCT Filed: Aug. 2, 2023
(86) PCT No.: PCT/EP2023/071411

§ 371 Date: Jan. 31, 2025

(30) Foreign Application Priority Data
Aug. 2, 2022 (EP) 22188328.3
Sep. 28, 2022 (EP) 22198444.6

(51) Int. Cl. H01L 23/373; H01L 21/48

(52) U.S. Cl. CPC H01L 23/3736; H01L 21/4878; H01L 21/4882; H01L 23/3735

(57) ABSTRACT

In a method for producing a semiconductor module, a heatsink is produced from a first metal material and a cavity with a base surface and a wall portion is introduced in a heatsink surface such as to form an obtuse angle between the base surface and the wall portion. In addition, a depression is introduced into the base surface of the cavity which depression is smaller than the base surface of the cavity. A second metal material is applied in the cavity and the depression using a thermal spraying method to form a heat-spreading layer of different thicknesses, with the second metal material having a thermal conductivity which is higher than a thermal conductivity of the first metal material. A semiconductor arrangement is connected to the heat-spreading layer.

The invention relates to a method for producing a semiconductor module having at least one semiconductor arrangement and a heatsink, comprising the following steps: providing a heatsink which is produced from a first metal material; introducing a cavity into a heatsink surface, wherein the cavity has a base surface which in particular extends in parallel with the heatsink surface, and at least one wall portion; applying a second metal material, which has a higher thermal conductivity than the first metal material, in the cavity using a thermal spraying method to form a heat-spreading layer; and connecting the semiconductor arrangement to the heat-spreading layer.

The invention further relates to a semiconductor module having at least one semiconductor arrangement and a heatsink which is produced from a first metal material and comprises at least one cavity, which has a base surface which in particular extends in parallel with the heatsink surface, and at least one wall portion, wherein a second metal material, which has a higher thermal conductivity than the first metal material, is applied in the cavity using a thermal spraying method to form a heat-spreading layer, wherein the semiconductor arrangement is connected to the heat-spreading layer.

The invention additionally relates to a power converter having at least one such semiconductor module.

In addition, the invention relates to a computer program product, comprising commands, which when the program is executed by a computer cause said computer to simulate an, in particular thermal and/or electrical, behavior of such a semiconductor module.

In such power converters, semiconductor arrangements are generally attached to a heatsink. A power converter is for example to be understood as a rectifier, an inverter, a converter or a DC-DC converter. The semiconductor arrangements are normally designed as electronics modules, which have a housing and are screwed to the heatsink via a solid metal support plate. The semiconductor arrangements can further be directly connected to the heatsink, i.e. without an additional connecting element such as a baseplate. The semiconductor arrangements can inter alia comprise transistors, in particular Insulated gate bipolar transistors (IGBTs) and/or metal-oxide semiconductor field-effect transistors (MOSFETs).

Published patent application WO 2011/024377 A1 describes a semiconductor module having a heat radiation element with a first element which contains aluminum, and a second element which contains copper, which is embedded in the first element and the sides of which are enclosed by the first element; and a semiconductor element, which is thermally connected to the heat radiation element.

Published patent application WO 2022/002464 A1 describes a power module having at least two power units, which each comprise at least one power semiconductor and a substrate. In order to reduce the installation space required for the power module and to improve cooling, it is proposed that the respective at least one power semiconductor is connected, in particular in a material-bonded manner, to the respective substrate, wherein the substrates of the at least two power units are each directly connected in a material-bonded manner to a surface of a common heatsink. The heatsink is produced from a first metal material. Cavities are introduced on its surface, and are filled with a second metal material, wherein the second metal material has a higher thermal conductivity than the first metal material. The second metal material is introduced into the cavities by means of an additive method, for example by means of cold gas spraying.

Applying the second metal material using an additive method brings with it challenges as regards thermal contacting in the cavity. Against this backdrop, it is an object of the present invention to improve thermal contacting of the second metal material in the cavity.

This object is inventively achieved in a method of the type mentioned in the introduction, in that when introducing the cavity an obtuse angle is in each case formed between the base surface and the at least one wall portion.

The object is further inventively achieved by a semiconductor module of the type mentioned in the introduction, in that an obtuse angle is formed between the base surface and the at least one wall portion.

The object is additionally inventively achieved by a power converter having at least one such semiconductor module.

In addition, the object is inventively achieved by a computer program product, comprising commands, which when the program is executed by a computer cause said computer to simulate an, in particular thermal and/or electrical, behavior of such a semiconductor module.

The advantages and preferred embodiments set out below in respect of the method can be transferred analogously to the semiconductor module, the power converter and the computer program product.

The invention is based on the consideration of improving the thermal connection of heat-spreading layers in cavities of a heatsink for a semiconductor module, which are applied using a thermal spraying method, by improving the adhesion of the applied particles. To produce such heat-spreading layers a cavity is introduced into a heatsink surface, wherein the cavity has a base surface, which in particular extends in parallel with the heatsink surface, and at least one wall portion. For example, the base surface is designed to be rectangular or square and the cavity has four wall portions. Alternatively, the cavity can have an elliptical or circular base surface with a circumferential wall portion. The cavity can for example be introduced by means of a cutting method, in particular milling. In a further step a second metal material, which has a higher thermal conductivity than the first metal material of the heatsink, is applied to the base surface and the at least one wall portion of the cavity using a thermal spraying method, as a result of which the heat-spreading layer is formed in the cavity. For example, the first metal material is an aluminum alloy, while the second metal material contains copper or a copper alloy. One example of a thermal spraying method is inter alia cold gas spraying, wherein particles of the second metal material, in particular copper particles, are sprayed on, as a result of which a material-bonded connection is formed. By connecting the semiconductor arrangement to the heat-spreading layer an optimized cooling due to heat spread is achieved during operation of the semiconductor module.

When the cavity is introduced, an obtuse angle is formed in each case between the base surface and the at least one wall portion, wherein an obtuse angle is defined in this context as an angle of between 95° and 175°. Consequently, the result is that the at least one wall portion, which in particular has a base surface which extends in parallel with the heatsink surface, forms an acute angle in the range of between 5° and 85° to the heatsink surface, so that the cavities have a substantially trapezoidal cross-sectional surface. An Increase in surface area is inter alia achieved due to such an angle, this having a positive effect on the adhesion of the second metal material in the cavities. The increase in surface area is also expedient for heat transfer into the heatsink. Furthermore, a spray particle jet of the thermal spraying method strikes at a more favorable angle, so that stronger adhesion and thus improved thermal contacting of the second metal material in the cavity is achieved.

A computer program product, which comprises commands, which when the program is executed by a computer cause said computer to simulate an, in particular thermal and/or electrical, behavior of the described semiconductor module, can comprise a “digital twin” or be designed as such. Such a digital twin is for example shown in the published patent application US 2017/0286572 A1. The contents of the disclosure in US 2017/0286572 A1 are also included by reference in the present application. The “digital twin” is for example a digital representation of the components that are relevant to the operation of the semiconductor module.

In the base surface of the cavity at least one additional depression is Introduced, which is smaller than the base surface of the cavity, wherein the second metal material is applied using the thermal spraying method in the cavity and the at least one additional depression, so that a heat-spreading layer is formed, which has different thicknesses. The at least one additional depression can have a rectangular or square base surface. For example, an obtuse angle is formed between a base surface and a wall portion of the depression, and can correspond to or differ from the obtuse angle of the cavity. Due to the obtuse angle the additional depressions likewise have a substantially trapezoidal cross-section. An additional depression filled with the second metal material ensures a local thickening of the heat-spreading layer, which improves the thermal connection of the semiconductor arrangement, for example when hotspots occur.

A further form of embodiment provides that the obtuse angle between the base surface and the at least one wall portion lies in the range of between 95° and 150°, in particular 110° and 150°, further in particular 130° and 150°. Due to such an angle optimized adhesion and thus improved thermal contacting of the second metal material in the cavities is achieved.

A further form of embodiment provides that the second metal material is applied at a spray angle of the thermal spraying method in the range of between 60° and 90°, in particular 70° and 90°. For example, particles of the second metal material are applied by means of a spray device, which in particular comprises a spray gun, in a spray jet, which can also be referred to as a spray particle jet, wherein the spray jet strikes at a spray angle. A spray angle in the range of between 60° and 90° ensures that a ricochet of particles is minimized during the thermal spraying method and the particles can be applied to the support material in a defined manner. In addition to the obtuse angle between the base surface and the at least one wall portion, an in particular dynamic or position-dependent tilting of the spray device can also enable an adjustment of such a spray angle in the region of the at least one wall portion.

A further form of embodiment provides that after the second metal material is applied the heatsink surface is face-milled. In this way a flat surface of the heat-spreading layer is produced and a flush connection of the heat-spreading layer to the heatsink surface is achieved, so that for example a flat substrate of the semiconductor arrangement can be connected to the heat-spreading layer easily, in a space-saving manner and with little thermal resistance.

A further form of embodiment provides that when the cavity is introduced between the base surface and at least one wall portion and/or between at least two wall portions, a concave curved mold surface is formed. Such a concave curved mold surface can for example be produced by a cutting method, in particular by means of a rotating milling tool, and results in an increase in surface area in the connecting region between the base surface and at least one wall portion or between at least two wall portions, as a result of which the adhesion and thus the thermal contacting of the second metal material in the cavity is improved.

A further form of embodiment provides that the semiconductor arrangement comprises at least one semiconductor element and a substrate, wherein the substrate of the semiconductor arrangement is connected over the whole surface to the heat-spreading layer. A substrate is inter alia a dielectric material layer metallized on both sides. The substrate can for example be designed as a DCB (direct copper bonded) substrate, wherein the dielectric material layer can contain aluminum oxide or aluminum nitride. The at least one semiconductor element can inter alia have an, in particular vertical, transistor and/or a diode. The, in particular vertical, transistor can inter alia be designed as an insulated gate bipolar transistor (IGBT). A good thermal connection of the at least one semiconductor element is achieved via a whole-surface connection to the heat-spreading layer.

A further form of embodiment provides that the substrate of the semiconductor arrangement is directly connected in a material-bonded manner to the heat-spreading layer. The direct material-bonded connection to the heat-spreading layer of the heatsink can be produced inter alia by soldering, sintering or adhesion. A direct material-bonded connection is to be understood as a direct connection which includes connection means for producing the material-bonded connection such as adhesive, solder alloy, sintering paste, etc., but excludes additional connecting elements such as an additional conductor, a spacer, a support plate, thermal paste, etc. By omitting such additional connecting elements, an improved thermal connection of the at least one semiconductor element is achieved, so that improved cooling takes place. In addition, installation space is saved due to the direct material-bonded connection.

A further form of embodiment provides that a surface of the heat-spreading layer substantially corresponds to an area of the substrate, wherein the substrate of the semiconductor arrangement is connected over the whole surface to the heat-spreading layer. For example, the heat-spreading layer is substantially flush with the substrate. Such a purposeful arrangement of the heat-spreading layer is cost-effective and an optimized thermal connection of the semiconductor arrangement is achieved.

A further form of embodiment provides that the at least one additional depression is arranged inside a perpendicular projection area of at least one semiconductor element. For example, an additional depression can have a base surface which is adapted to a base surface or to a footprint of a semiconductor element. Such an additional depression arranged underneath at least one semiconductor element and filled with the second metal material ensures a local thickening of the heat-spreading layer, which improves the thermal connection of the semiconductor element of the semiconductor arrangement.

The invention is described and explained in greater detail below on the basis of the exemplary embodiments shown in the figures.

It is shown in:

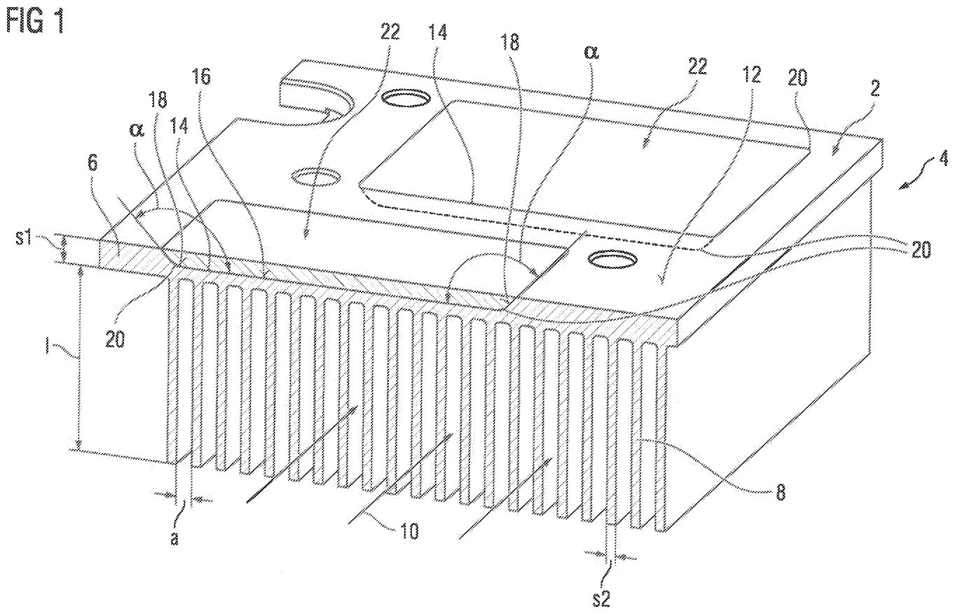

FIG. 1 a schematic three-dimensional sectional representation of a heatsink for a semiconductor module,

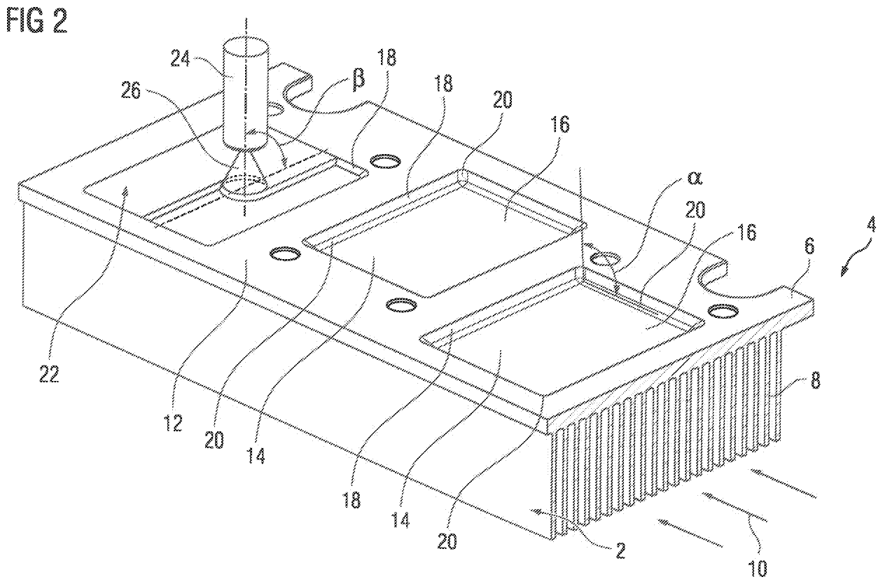

FIG. 2 a schematic three-dimensional representation of a thermal spraying method,

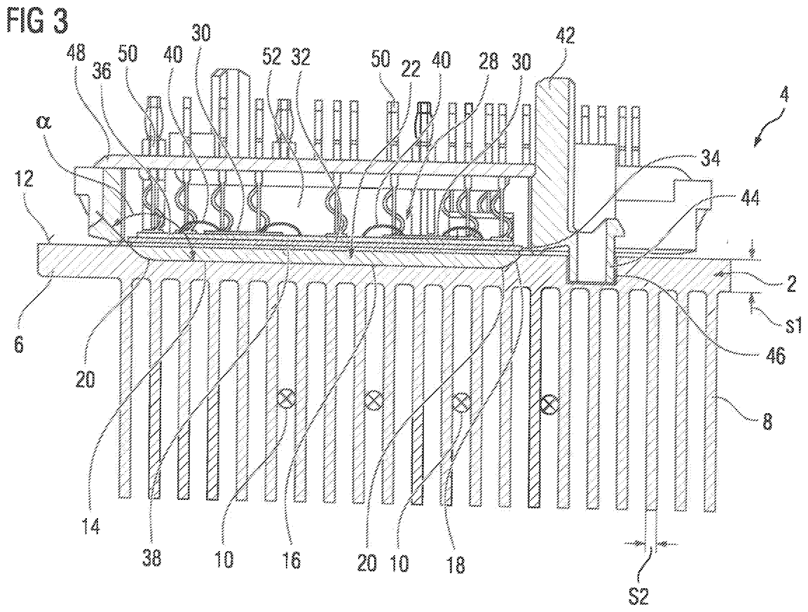

FIG. 3 a schematic cross-sectional representation of a first form of embodiment of a semiconductor module,

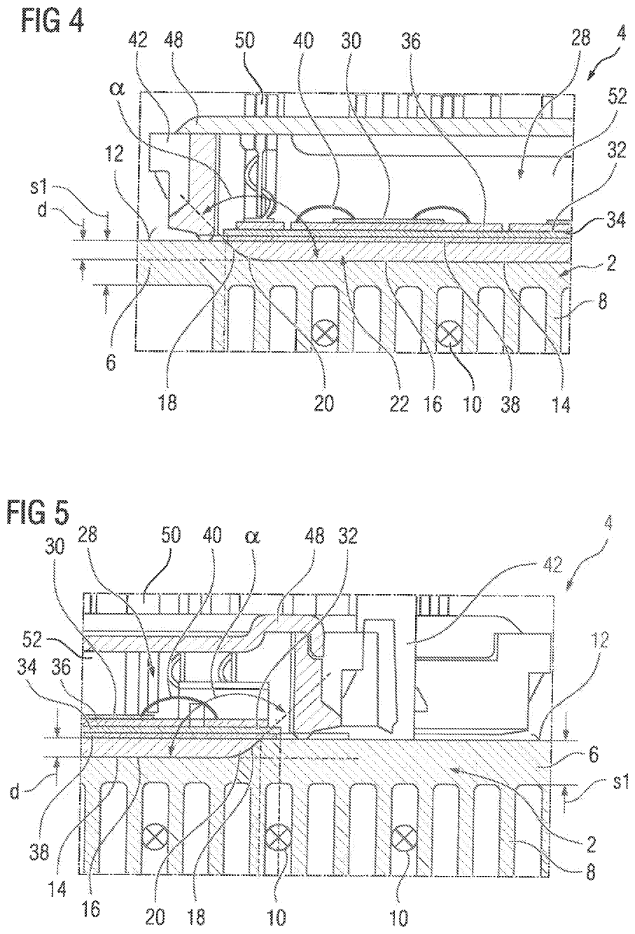

FIG. 4 an enlarged schematic cross-sectional representation of a first form of embodiment of a semiconductor module,

FIG. 5 an enlarged schematic cross-sectional representation of a second form of embodiment of a semiconductor module,

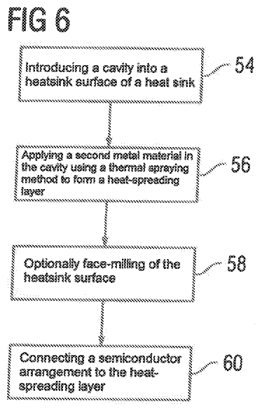

FIG. 6 a flow diagram of a method for producing a semiconductor module,

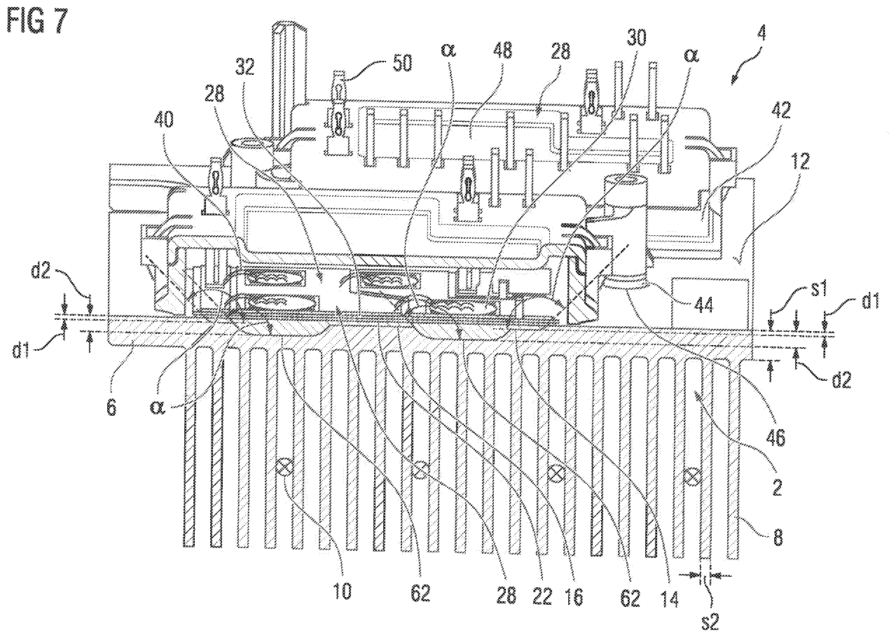

FIG. 7 a schematic three-dimensional sectional representation of a third form of embodiment of a semiconductor module,

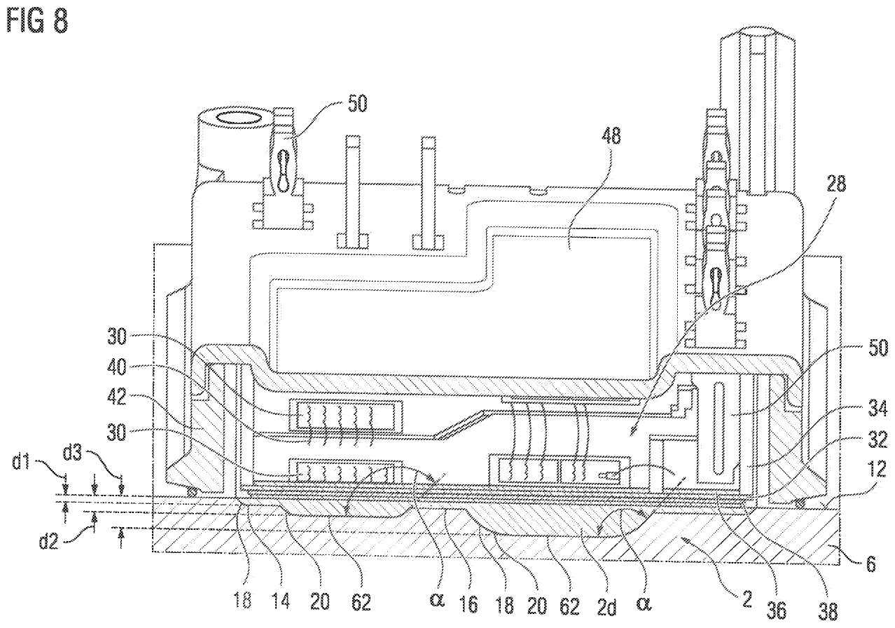

FIG. 8 a schematic three-dimensional sectional representation of a fourth form of embodiment of a semiconductor module, and

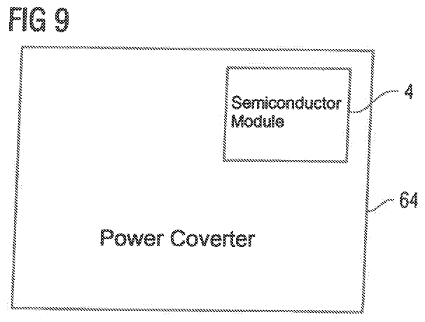

FIG. 9 a schematic representation of a power converter.

The exemplary embodiments described below are preferred forms of embodiment of the invention. In the case of the exemplary embodiments, the described components of the forms of embodiment each represent individual features of the invention which are to be considered independently of one another and which also develop the Invention independently of one another in each case and are thus also to be regarded as a component of the invention individually or in a combination other than that shown. Furthermore, the described forms of embodiment can also be supplemented by further features of the invention that have already been described.

The same reference characters have the same meaning in the various figures.

FIG. 1 shows a schematic three-dimensional sectional representation of a heatsink 2 for a semiconductor module 4. The heatsink has a baseplate 6 with cooling ribs 8, wherein the cooling ribs 8 are connected to the baseplate 6, By way of example, in FIG. 1 the baseplate 6 and the cooling ribs 8 of the heatsink 2 are designed integrally. The heatsink 2 is configured by the cooling ribs 8 to conduct an, in particular gaseous, cooling fluid in a coolant flow direction 10, wherein the coolant flow direction 10 extends substantially in parallel with a flat heatsink surface 12. The cooling fluid is for example air, which flows via a fan, not shown in FIG. 1 for reasons of clarity, in the coolant flow direction 10 via the cooling ribs 8 of the heatsink 2. The baseplate 6 has a substantially constant first thickness s1 of between 3.5 mm and 5 mm, in particular 3.5 mm and 4 mm, while the cooling ribs 8 have a second thickness s2 which is less than the first thickness s1 of the baseplate 6.

The heatsink 2 is produced from a first metal material. The first metal material can inter alia be an aluminum alloy, which for example has a silicon content of between 0.1% and 1.0%, in particular 0.1% and 0.6%, Such a heatsink 2 can inter alia be produced by means of extrusion. Furthermore, the cooling ribs 8 of the heatsink 2 produced from the aluminum alloy are arranged such that a ratio of a length I of the cooling ribs 8 to a spacing a between the cooling ribs 8 is at least 10:I/a≥10.

In addition, the heatsink 2 has by way of example two cavities 14 arranged in the baseplate 6, which have an, in particular substantially flat, base surface 16 extending in parallel with the heatsink surface 12, and wall portions 18. The base surface 16 is by way of example designed to be rectangular. An obtuse angle α is formed between the base surface 16 and the wall portions 18, and by way of example is 140°, so that the cavities 14 have a substantially trapezoidal cross-sectional surface. Alternatively, the angle α between the base surface 16 and the wall portions 18 can be in the range of between 95° and 150°, in particular 110° and 150°, further in particular 130° and 150°. The introduction of the cavities 14 can for example be carried out by means of a cutting method, for example milling. A concave curved mold surface 20 is formed between the base surface 16 and the wall portions 18 as well as between adjacent wall portions 18.

A second metal material is arranged in the cavities 14, and has a higher thermal conductivity than the first metal material. For example, the second metal material contains copper or a copper alloy. The second metal material is applied using a thermal spraying method, for example by means of cold gas spraying, to form a heat-spreading layer 22, wherein the second metal material is connected in a material-bonded manner by the thermal spraying method to the first material. In addition, the second metal material of the heat-spreading layers 22 arranged in the cavities 14 is substantially flush with the heatsink surface 12, so that a flat surface is formed. Such a flush connection can be produced for example by face-milling. Due to the obtuse angle α between the base surface 16 and the wall portions 18, particles of the second metal material strike at a more favorable angle during the thermal spraying method, so that stronger adhesion and thus improved thermal contacting of the second metal material in the cavities 14 is achieved. The concave mold surfaces 20 between the base surface 16 and the wall portions 18 as well as between the adjacent wall portions 18 also allow a more favorable spray angle and thus improved thermal contacting.

FIG. 2 shows a schematic three-dimensional representation of a thermal spraying method. By way of example, in FIG. 2 an application of the second metal material by means of cold gas spraying is shown. The second metal material is applied by a spraying device 24, which for example comprises a spray gun, in a spray jet 26, which can also be referred to as a spray particle jet. The spraying procedure is carried out at a spray angle β in the range of between 60° and 90°, in particular 70° and 90°. Besides the obtuse angle α between the base surface 16 and the wall portions 18, a dynamic or position-dependent tilting of the spray device 24 also results in an optimization of the spray angle β in the area of the wall portion 18. The further design of the heatsink 2 in FIG. 2 corresponds to the design in FIG. 1.

FIG. 3 shows a schematic three-dimensional sectional representation of a first form of embodiment of a semiconductor module 4, which besides the heatsink 2 comprises a semiconductor arrangement 28. The semiconductor arrangement 28 has semiconductor elements 30, which are designed as an, in particular vertical, transistor or as a diode. A transistor can be designed as inter alia an insulated gate bipolar transistor (IGBT), as a metal-oxide semiconductor field-effect transistor (MOSFET) or as a bipolar transistor. An, in particular anti-parallel, diode can be associated with a transistor. The semiconductor elements 30 are connected to a substrate 32 in a material-bonded manner, wherein the material-bonded connection can be produced inter alia by soldering and/or sintering.

The substrate 32 has a dielectric material layer 34, which contains a ceramic material, for example aluminum nitride or aluminum oxide, or an organic material, for example a polyamide. The dielectric material layer 34 can have a thickness of between 25 μm and 400 μm, in particular 50 μm and 250 μm. In addition, the substrate 32 has a structured first metallization 36 on a side facing the semiconductor elements 30 and a second metallization 38 on a side facing away from the semiconductor elements 30. The substrate 32 of the semiconductor arrangement 28 is directly connected over the whole surface in a material-bonded manner to the heat-spreading layer 22 of the heatsink 2 via the second metallization 38. In addition, the cavity 14 is designed such that the heat-spreading layer 22 is substantially flush with the substrate 32. The material-bonded connection to the heatsink 2 is produced by soldering or sintering. The direct material-bonded connection to the heat-spreading layer 22 of the heatsink 2 can be produced inter alia by soldering, sintering or adhesion. A direct material-bonded connection is to be understood as a direct connection which includes connection means for producing the material-bonded connection such as adhesive, tin solder, sintering paste, etc., but excludes additional connecting elements such as an additional conductor, a spacer, a support plate, thermal paste, etc. The semiconductor elements 30 are connected to the first metallization 36 of the substrate 32 on a side facing away from the substrate 32 via wiring elements 40. The wiring elements 40 can inter alia comprise at least one bonding wire and/or at least one ribbon bond.

The semiconductor arrangement 28 is arranged in a housing 42, which for example is produced from a plastic material. The housing 42 is arranged on the heatsink 2 via a form-fit connection 44 with a blind hole 46. Freely positionable contacts 50 extending through a housing cover 48 are connected in a material-bonded manner, for example by soldering or sintering, to the first metallization 36 of the substrate 32. The semiconductor arrangement 28 is potted inside the housing 42 with a potting compound 52. The further design of the heatsink 2 in FIG. 3 corresponds to the design in FIG. 1.

FIG. 4 shows an enlarged schematic cross-sectional representation of a first form of embodiment of a semiconductor module 4 in the region of an obtuse angle α between the base surface 16 and a wall portion 18 of the cavity 14. A thickness d of the heat-spreading layer 22 is greater than half the first thickness s1 of the baseplate 6 of the heatsink 2, as a result of which a very good thermal connection of the semiconductor elements 30 is achieved. The heat-spreading layer 22 is substantially flush with the substrate 32, wherein the obtuse angle α is designed so that the heat-spreading layer 22 has its maximum thickness d underneath the semiconductor elements 30. The further design of the semiconductor module 4 in FIG. 4 corresponds to the design in FIG. 3.

FIG. 5 shows an enlarged schematic cross-sectional representation of a second form of embodiment of a semiconductor module 4 in the region of an obtuse angle α between the base surface 16 and a wall portion 18 of the cavity 14. A thickness d of the heat-spreading layer 22 is less than half the first thickness s1 of the baseplate 6 of the heatsink 2, as a result of which a sufficient thermal connection of the semiconductor elements 30, in particular for lower powers, is achieved. The substrate 32 protrudes over the heat-spreading layer 22, wherein the heat-spreading layer 22 has its maximum thickness d underneath the semiconductor elements 30. The further design of the semiconductor module 4 in FIG. 5 corresponds to the design in FIG. 4.

FIG. 6 shows a flow diagram of a method for producing a semiconductor module 4, which is represented in one of FIGS. 3 to 5. The method includes the introduction 54 of a cavity 14 into a heatsink surface 12 of a heatsink 2, which is produced from a first metal material. The cavity 14 has a flat base surface 16 and at least one wall portion 18. When introducing 54 the cavity 14 an obtuse angle α is in each case formed between the base surface 16 and the wall portions 18, wherein an obtuse angle in this context is between 95° and 175° (95°≤α≤175°). Inter alia, the cavity 14 can be designed as a truncated pyramid in the case of a rectangular or square base surface 16 or as a truncated cone in the case of an elliptical or circular base surface 16.

In a further step, an application 56 of a second metal material, which has a higher thermal conductivity than the first metal material, is carried out in the cavity 14 using a thermal spraying method to form a heat-spreading layer 22. In particular, the second metal material is applied by means of cold gas spraying.

The application 56 of the second metal material is optionally followed by face-milling 58 of the heatsink surface 12, so that the heat-spreading layer 22 is flush with the heatsink surface 12.

In a further step a connection 60 of the semiconductor arrangement 28 to the heat-spreading layer 22 is carried out. The semiconductor arrangement 28 has at least one semiconductor element 30 and a substrate 32, wherein the substrate 32 of the semiconductor arrangement 28 is directly connected in a material-bonded manner, in particular over the whole surface, to the heat-spreading layer 22. The material-bonded connection to the heatsink 2 can be produced inter alia by soldering or sintering.

FIG. 7 shows a schematic three-dimensional sectional representation of a third form of embodiment of a semiconductor module 4 with by way of example two semiconductor arrangements 28, which are connected on a common heatsink 2. The base surface 16 of the cavity 14 has additional depressions 62, which are smaller than the base surface 16 of the cavity 14 and are arranged inside a perpendicular projection surface of the semiconductor elements 30, The additional depressions 62 protrude over the base surface of the semiconductor elements 30. The second metal material is introduced in the cavity 14 and in the additional depressions 62 using the thermal spraying method, so that a heat-spreading layer 22 is formed, which has different thicknesses d1, d2, wherein a second thickness d2 is greater than a first thickness d1. The additional depressions 62 arranged underneath the semiconductor elements 30 and filled with the second metal material ensure a local thickening of the heat-spreading layer 22, which improves the thermal connection of the semiconductor elements 30.

Like the cavity 14, the additional depressions 62 have a substantially flat rectangular base surface 16 and wall portions 18. An obtuse angle α is formed between the base surface 16 and the wall portions 18, which can correspond to or differ from the obtuse angle α of the cavity. Due to the obtuse angle α, the additional depressions 62 likewise have a substantially trapezoidal cross-section. Concave curved mold surfaces 20 are likewise formed between the base surface 16 and the wall portions 18 as well as between adjacent wall portions 18 of the additional depressions 62. The further design of the semiconductor module 4 in FIG. 7 corresponds to the design in FIG. 3.

FIG. 8 shows a schematic three-dimensional sectional representation of a fourth form of embodiment of a semiconductor module 4. The base surface 16 of the cavity 14 has various deep additional depressions 62, which are arranged inside a perpendicular projection surface of the semiconductor elements 30. By filling the various deep additional depressions 62 with the second metal material using the thermal spraying method a heat-spreading layer 22 is formed, which has different thicknesses d1, d2, d3, wherein a second thickness d2 is greater than a first thickness d1 and a third thickness d3 is greater than a second thickness d2. By varying the thickness d2, d3 of the heat-spreading layer 22 by means of additional depressions 62 arranged underneath the semiconductor elements 30 and filled with the second metal material, a thermal connection can be adjusted to a heat loss of the semiconductor elements 30 occurring during operation. For example, due to the greater waste heat to be dissipated the heat-spreading layer 22 under an IGBT has a greater thickness d2, d3 than under a diode. The further design of the semiconductor module 4 in FIG. 8 corresponds to the design in FIG. 7.

FIG. 9 shows a schematic representation of a power converter 64 having a semiconductor module 4. The power converter 64 can comprise more than one semiconductor module 4.

In summary, the invention relates to a method for producing a semiconductor module 4 having at least one semiconductor arrangement 28 and a heatsink 2 comprising the following steps: providing a heatsink 2 which is produced from a first metal material; introducing 54 a cavity 14 into a heatsink surface 12, wherein the cavity 14 has a base surface 16 which in particular extends in parallel with the heatsink surface 12, and at least one wall portion 18; applying 56 a second metal material, which has a higher thermal conductivity than the first metal material, in the cavity 14 using a thermal spraying method to form a heat-spreading layer 22; connecting 60 the semiconductor arrangement 28 to the heat-spreading layer 22. In order to improve thermal contacting of the second metal material in the cavity 14, it is proposed that when introducing 54 the cavity 14 an obtuse angle α is in each case formed between the base surface 16 and the at least one wall portion 18.

18. (canceled)

19. A method for producing a semiconductor module, the method comprising:
producing a heatsink from a first metal material;
introducing in a heatsink surface a cavity with a base surface and a wall portion such as to form an obtuse angle between the base surface and the wall portion;
introducing into the base surface of the cavity a depression which is smaller than the base surface of the cavity;
applying a second metal material in the cavity and the depression using a thermal spraying method to form a heat-spreading layer of different thicknesses, with the second metal material having a thermal conductivity which is higher than a thermal conductivity of the first metal material; and
connecting a semiconductor arrangement to the heat-spreading layer.

20. The method of claim 19, wherein the base surface extends in parallel with the heatsink surface.

21. The method of claim 19, wherein the second metal material is applied at a spray angle of the thermal spraying method in a range of between 60° and 90°, in particular 70° and 90°.

22. The method of claim 19, further comprising face-milling the heatsink surface after applying the second metal material.

23. The method of claim 19, further comprising forming a concave curved mold surface as the cavity is introduced between the base surface and the wall portion or between at least two wall portions of the cavity.

24. The method of claim 19, wherein the semiconductor arrangement comprises a semiconductor element and a substrate, the method further comprising connecting the substrate of the semiconductor arrangement flush with the heat-spreading layer.

25. The method of claim 24, wherein the substrate of the semiconductor arrangement is directly connected in a material-bonded manner to the heat-spreading layer.

26. The method of claim 24, wherein a surface of the heat-spreading layer substantially corresponds to a surface of the substrate, wherein the substrate of the semiconductor arrangement is connected over a whole surface to the heat-spreading layer.

27. The method of claim 24, further comprising arranging the depression inside a perpendicular projection surface of the semiconductor element.

28. A semiconductor module, comprising:
a heatsink made from a first metal material and comprising a cavity with a base surface and a wall portion such that an obtuse angle is formed between the base surface and the wall portion, said base surface of the cavity comprising a depression which is smaller than the base surface of the cavity;
a second metal material applied in the cavity and the depression using a thermal spraying method to form a heat-spreading layer of different thicknesses, with the second metal material having a thermal conductivity which is higher than a thermal conductivity of the first metal material; and
a semiconductor arrangement connected to the heat-spreading layer.

29. The semiconductor module of claim 28, wherein the base surface extends in parallel with a heatsink surface.

30. The semiconductor module of claim 28, wherein the obtuse angle between the base surface and the wall portion is in a range of between 95° and 150°, in particular 110° and 150°, further in particular 130° and 150°.

31. The semiconductor module of claim 29, wherein the second metal material is connected in a material-bonded manner to the first metal material and is substantially flush with the heatsink surface.

32. The semiconductor module of claim 28, wherein a concave curved mold surface is formed between the base surface and the wall portion or between at least two wall portions of the cavity.

33. The semiconductor module of claim 28, wherein the semiconductor arrangement comprises a semiconductor element and a substrate, said substrate of the semiconductor arrangement being connected flush with the heat-spreading layer.

34. The semiconductor module of claim 33, wherein the substrate of the semiconductor arrangement is directly connected in a material-bonded manner to the heat-spreading layer.

35. The semiconductor module of claim 33, wherein the substrate of the semiconductor arrangement is connected over a whole surface to the heat-spreading layer, and wherein the heat-spreading layer is substantially flush with the substrate.

36. The semiconductor module of claim 33, wherein the depression is arranged inside a perpendicular projection surface of the semiconductor element.

37. A power converter, comprising the semiconductor module of claim 28.

38. A computer program product, comprising a computer program embodied on a non-transitory computer readable medium comprising commands which, when the computer program is executed by a computer, cause the computer to simulate an, in particular thermal and/or electrical, behavior of the semiconductor module of claim 28.
